(19) United States
(12) Patent Application Publication
(10) Pub. No.: US 2018/0320993 A1
(43) Pub. Date: Nov. 8, 2018

(54) LIQUID COLD PLATE HEAT EXCHANGER

(71) Applicant: Aavid Shenzen Thermal Energy System Co. Ltd., Shenzhen (CN)

(72) Inventors: Sonawane Parag, Magarpatta City (IN); Bert Feng, ShenZhen (CN)

(73) Assignee: Aavid Shenzen Thermal Energy System Co. Ltd., Shenzhen (CN)

(21) Appl. No.: 15/972,592

(22) Filed: May 7, 2018

(30) Foreign Application Priority Data
May 8, 2017 (CN) 201720502689.7

(51) Int. Cl. F28F 9/00; F28F 3/12; F28F 3/02; H01L 23/473; H01L 23/40; H01L 21/48

(52) U.S. Cl. CPC F28F 9/005; F28F 3/12; H01L 21/4882; H01L 23/473; H01L 23/40; F28F 3/02

(57) ABSTRACT

A liquid cold plate heat exchanger includes a heat sink with a plurality of fins received in a cavity between a base plate and a cap. A spring plate may be positioned between a top surface of the heat sink, e.g., over fins of the heat sink, and a lower surface of the cap in the cavity. The spring plate may at least partially and/or completely fill a gap between the heat sink and the cap, aiding in thermal conduction between the cap and heat sink.

### RELATED APPLICATION

This Application claims priority from Chinese Application No. 201720502689.7, filed May 8, 2017, entitled “A LEAKPROOF STRUCTURE FOR HIGH TEMPERATURE VACUUM BRAZING LIQUID COLD PLATE” which is herein incorporated by reference in its entirety.

### FIELD OF INVENTION

A liquid cold plate heat exchanger, e.g., for cooling electronics using a circulated flow of cooling fluid.

### BACKGROUND

With the development of electronic technology, heat dissipation requirements for computer processing devices, e.g., integrated circuits or chips, has increased, requiring ever higher efficiency liquid cold plate heat exchange devices to remove the heat generated by these devices.

### SUMMARY OF INVENTION

One type of device used to cool electronics or other heat generating devices is a liquid cold plate heat exchanger that thermally couples a heat generating device (such as a computer processor) to a heat sink that includes a plurality of fins. At least a portion of the heat sink may be enclosed in a cavity in which a cooling fluid is circulated so that heat may be transferred from the heat sink to the fluid and removed from the cavity. In one embodiment, a heat sink may be sandwiched between upper and lower plates so that the heat sink is located in a cavity defined by the plates. As an example, the heat sink may be placed on the upper surface of a lower plate or base, and a top plate or cap having a cavity formed in an underside of the cap may be placed over the base so the heat sink is enclosed in the cavity. The base and cap may be secured together to form a liquid-tight seal around the cavity so that cooling fluid can be circulated into the cavity without leaking.

Due to manufacturing tolerances and other difficulties, the heat sink and the cavity must be sized so that the top surface of the heat sink does not contact the portion of the cap at the cavity when the cap is placed over the base. That is, if the heat sink top surface were to contact the cap when the cap is placed over the heat sink and the base, the heat sink may prevent the cap from being positioned properly relative to the base, e.g., in direct contact with the base. This can cause problems, such as preventing proper brazing or other joining of the base and cap together so as to form a liquid-tight seal. To avoid these problems, the heat sink and cavity are made so a gap is present between the top surface of the heat sink and the cap when the cap is properly positioned on the base. However, this gap between the heat sink and the cap can prevent effective heat transfer between the heat sink and the cap. For example, because of the gap, heat cannot be transferred across the gap from the cap to the heat sink by conduction, but instead must transfer through the cooling fluid. This can limit the efficiency of cooling of the heat sink or cap, e.g., if a heat generating device is thermally coupled to the cap.

Embodiments in accordance with aspects of the invention can reduce or eliminate a gap between the heat sink and cap in such structures, reducing thermal resistance and improving efficiency. Alternately or in addition, manufacturing tolerances regarding the cavity size and/or heat sink size may be relaxed, and in some cases thermal resistance and or efficiency may be improved while allowing for relatively high heat joining operations such as vacuum brazing of the base and cap. In some cases, the gap between heat sink top surface and cap may be reduced to 0.1 mm or less. In some embodiments, a spring plate may be provided between the cap and the top surface of the heat sink, e.g., on top of the fins of the heat sink. The spring plate may have a floating top surface that contacts the cap and a bottom surface that contacts the heat sink. The cap may have a location groove in the lower surface of the cap that contacts the floating surface of the spring plate, e.g., to help locate the spring plate relative to the cap. The spring plate bottom surface may have good thermal and/or physical contact with heat sink top surface, e.g., may span across a plurality of fins. As a result, the spring plate may reduce or eliminate the gap between the cap and the heat sink, and the spring plate may function to transfer heat across the gap between the cap and heat sink top surface by conduction.

In one aspect of the invention, a liquid cold plate heat exchanger may include a base having an upper surface, and a heat sink having a plurality of fins arranged on the upper surface of the base. The heat sink may be thermally coupled to the base, e.g., so that heat transferred to the base by a heat generating device can be conducted to the heat sink. The plurality of fins of the heat sink may define a top surface of the heat sink, e.g., the heat sink may have a plurality of upstanding plate-shaped fins that extend upwardly from a bottom of the heat sink, are parallel to each other and are spaced apart with a distance between adjacent fins being 0.1 to 2 mm (or some other suitable value). A cap having a lower surface may be positioned over the upper surface of the base and the heat sink, and a spring plate may be positioned between the top surface of the heat sink and the lower surface of the cap. With the cap secured to the base, the spring plate may be arranged to exert an upward bias on the lower surface of the cap and a downward bias on the top surface of the heat sink. For example, the spring plate may have an upper portion that contacts the cap and a lower portion that contacts the heat sink, and the spring plate may be resilient so that it can exert a resilient bias on the cap and heat sink. In some cases, a gap between the top surface of the heat sink and the lower surface of the cap may be partially or completely filled by the spring plate, e.g., so that heat may be transferred by conduction by the spring plate between the heat sink and the cap. For example, a distance between lower surface of the cap in the cavity and the top surface of the heat sink may be between 0.1 mm and 0.2 mm, and the spring plate may partially or completely fill the gap in at least some areas.

In some embodiments, the heat sink may be located in a cavity between the base and the cap, and the cavity may be liquid tight so that a fluid cooling medium may be circulated through the cavity for heat transfer with the heat sink. In some cases, the cap includes a cavity in a portion of the lower surface arranged to receive and contact the spring plate and to receive at least a portion of the heat sink. However, in other embodiments, the base may include a cavity to receive at least a portion of the heat sink and/or the spring plate, and/or both the base and cap may include a cavity to receive the heat sink and/or spring plate. To enclose the heat sink in a liquid tight cavity, the cap and the base may be joined together in an area around the heat sink to enclose the heat sink in the cavity. In one particular embodiment, a portion of the upper surface of the base and a portion of the lower surface of the cap are secured directly together to form a liquid-tight seal around the heat sink. In other embodiments, the cap and base may be secured together by an intervening element, such as a spacer. The cap and base may be secured together in different ways, such as vacuum brazing or other relatively high heat operations. Thus, in some embodiments, the base, heat sink, cap and spring plate are arranged to withstand a temperatures required to secure the lower surface of the cap to the upper surface of the base by vacuum brazing, or can be arranged to withstand a temperature of 500 degrees C. for at least 1 hour. In some embodiments, the base, heat sink and/or cap may be made of copper or aluminum, and the spring plate may be made of stainless steel or other elastic material.

In some embodiments, the spring plate includes a heat sink contacting portion that contacts the heat sink top surface and a cap contacting portion that contacts the lower surface of the cap, and the heat sink contacting portion is located below the cap contacting portion. For example, the spring plate may be stamped or otherwise formed of a sheet of metal or other suitable material to form a bend between heat sink contacting and cap contacting portions. The bend may allow the spring plate to exert a resilient bias on the cap and heat sink. In some embodiments, the heat sink contacting portion is located between first and second cap contacting portions located at opposite ends of the spring plate. For example, the spring plate may be formed of a bent metal sheet that forms the heat sink contacting portion and the first and second cap contacting portions, and the heat sink contacting portion may be located in a lower plane positioned below an upper plane in which the first and second cap contacting portions are located. Thus, the spring plate may form a U-type shape or channel-type shape with cap contacting portions extending outwardly from the central U or channel portion. In some embodiments, the spring plate may be formed of a metal sheet having a thickness of 0.1 to 0.2 mm, and the thickness of the plate material may be close in size to a designed gap between the cap and top surface of the heat sink.

In another aspect of the invention, a liquid cold plate heat exchanger includes a base having an upper surface, and a heat sink having a plurality of fins arranged on the upper surface of the base with the plurality of fins defining a top surface of the heat sink. A cap may have a lower surface and a cavity formed in a portion of the lower surface with the cavity positioned over the upper surface of the base and the heat sink, e.g., so the heat sink is at least partially received into the cavity. A spring plate may be positioned between the top surface of the heat sink and the lower surface of the cap at the cavity so that when a portion of the lower surface of the cap around the cavity is secured to a portion of the upper surface of the base around the heat sink (e.g., by vacuum brazing), and the spring plate is arranged to exert an upward bias on the lower surface of the cap at the cavity and a downward bias on the top surface of the heat sink.

These and other aspects of the invention will be appreciated from the following description and claims.

### BRIEF DESCRIPTION OF THE DRAWINGS

Aspects of the invention are described with reference to the following drawings in which numerals reference like elements, and wherein:

FIG. 1 shows a side view and partial cross sectional view along the line 1-1 in FIG. 2 of a liquid cold plate in an illustrative embodiment;

FIG. 2 shows an exploded perspective view of the FIG. 1 embodiment;

FIG. 3 shows a bottom perspective view of the cap of the FIG. 1 embodiment;

FIG. 4 shows a side view of the spring plate in the FIG. 1 embodiment; and

FIG. 5 shows a side view of the base and heat sink of the FIG. 1 embodiment.

### DETAILED DESCRIPTION

Aspects of the invention are not limited in application to the details of construction and the arrangement of components set forth in the following description or illustrated in the drawings. Other embodiments may be employed and aspects of the invention may be practiced or be carried out in various ways. Also, aspects and/or different features of embodiments of the invention may be used alone or in any suitable combination with each other. Thus, the phraseology and terminology used herein is for the purpose of description and should not be regarded as limiting.

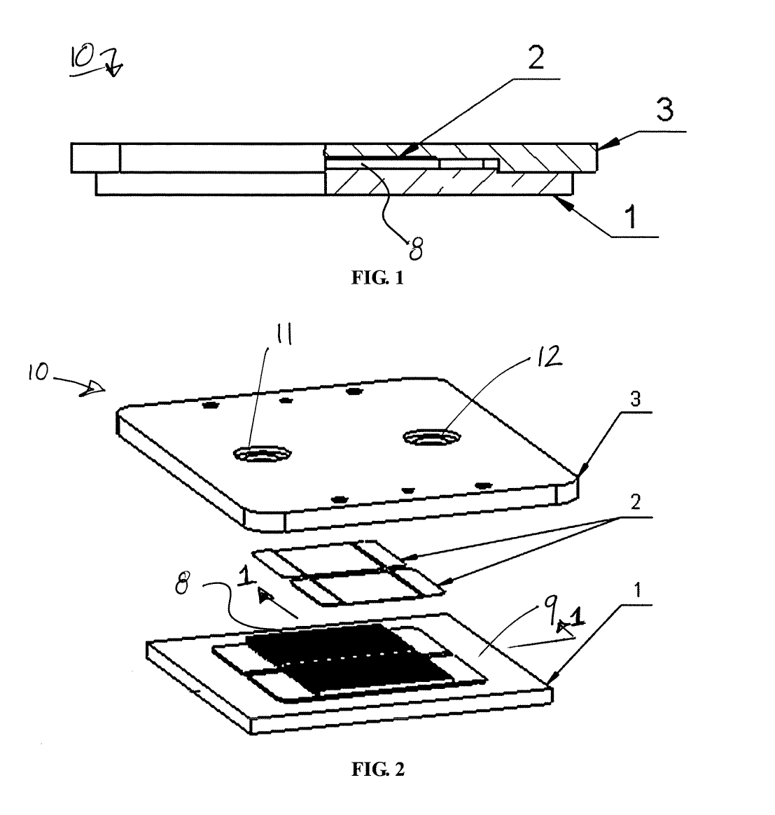

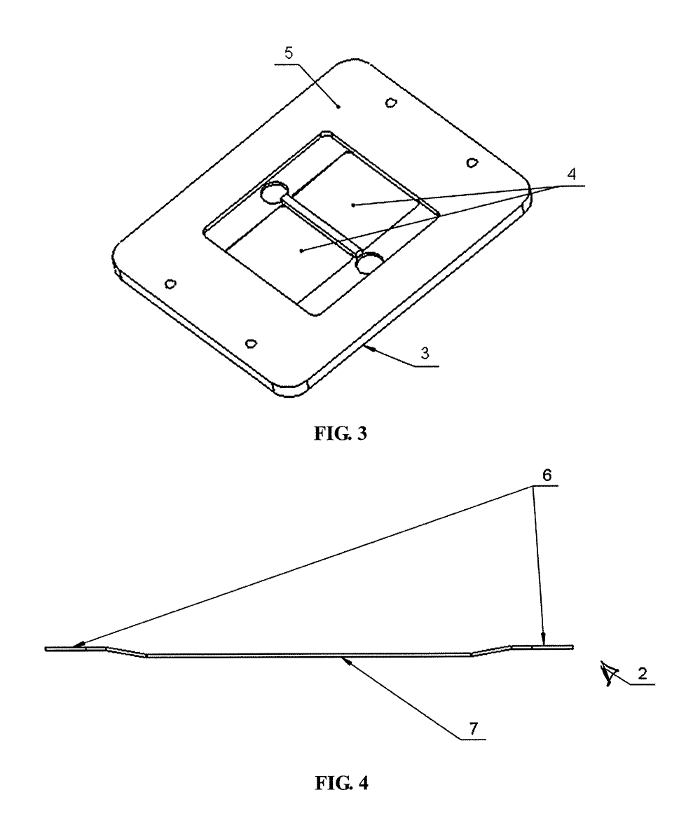

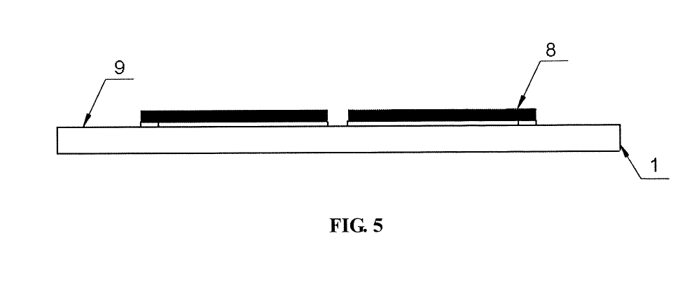

FIGS. 1 and 2 show a liquid cold plate heat exchanger 10 in an illustrative embodiment. The heat exchanger 10 includes a base 1, which may be made of a thermally conductive material such as aluminum or copper or other suitable material. Although not shown, the base 1 may be thermally coupled to a heat generating device, such as a computer processing device or other electronic component, to receive heat from the heat generating device. The base 1 may be thermally coupled to the heat generating device in any suitable way, such as by contacting the heat generating device to a bottom surface of the base 1. One or more heat sinks 8 are positioned on an upper surface 9 of the base 1 as can be seen in FIG. 5. The heat sink 8 may be arranged in any suitable way, e.g., formed of aluminum, copper or other conductive material and having a bottom wall with upstanding plate-like fins extending upwardly from the bottom wall. The heat sink 8 may be thermally coupled to the base 1 to receive heat from the base 1, e.g., the heat sink 8 may be fastened to the base 1 to receive heat by conduction. In some embodiments, the heat sink 8 may be formed unitarily with the base 1, e.g., by forming the base 1 to have a plurality of fins, pins or other elements to function as a heat sink. A cap 3 may be positioned over the heat sink 8 and base 1, e.g., to enclose the heat sink 8 in a cavity. In this embodiment and as can be seen in FIG. 3, the cap 3 may have a cavity 4 formed in a lower surface 5 of the cap 3 to at least partially receive the heat sink 8. Of course, the base 1 may include a cavity to at least partially receive the heat sink 8 rather than the cap 3, or both the cap 3 and base 1 may include a cavity to receive the heat sink 8. As can be seen in FIG. 1, with the cap 3 positioned over the base 1, the heat sink 8 may be enclosed in the cavity 4. In this embodiment, a portion of the lower surface 5 of the cap 3 may be attached to a portion of the upper surface 9 of the base 1 around the heat sink 8 so the heat sink 8 is enclosed in a fluid tight cavity 4. This may allow circulation of a cooling fluid into the cavity 4 for contact with the heat sink 8, e.g., via an inlet port 11 and outlet port 12 in the cap 3. Although the inlet and outlet ports 11, 12 are shown formed in an upper surface of the cap 3, such ports may be provided in any suitable location on the cap 3, base 1 or other portion of the heat exchanger 10. Attachment of the cap 3 and base 1 may be done in any suitable way, and in some embodiments the cap 3 and base 1 are attached by a vacuum brazing process that directly joins the cap 3 lower surface 5 portion with the base 1 upper surface 9 portion. In other cases, the cap 3 and base 1 may be joined by an intervening element, such as a spacer component that defines a cavity 4 in which the heat sink 8 is received and is positioned between the lower surface 5 of the cap 3 and the upper surface 9 of the base 1. This may allow the cap 3 and base 1 to have completely flat lower and upper surfaces, respectively. However, providing the lower surface 5 of the cap 3 with a cavity 4 may allow the cavity 4 to provide a locating function for the heat sink 8.

In accordance with an aspect of the invention, a spring plate 2 is provided between a top surface of the heat sink 8 and the lower surface of the cap 3. The spring plate 2 may provide significant advantages over an arrangement that lacks a spring plate 4 and instead has an open gap between the top surface of the heat sink 8 and the cap 3. For example, an open gap may preclude transfer of heat from the cap 3 to the heat sink 8 by conduction across the gap. In contrast, the spring plate 2 may at least partially or completely fill the gap in at least some areas, allowing for thermal conduction across the gap. Also, the spring plate 2 may help relax manufacturing tolerances because the heat sink 8 need not be made with a height that exactly matches the height of the cavity 4. Further, the spring plate 2 may exert a resilient or spring bias downwardly on the heat sink 8 (as well as upwardly on the cap 3) which may help maintain suitable contact between the heat sink 8 and the base 1, e.g., aiding in thermal conduction. In some cases, the gap between the top surface of the heat sink 8, which may be defined by a plurality of fins of the heat sink 8, and the lower surface of the cap 3 at the cavity 4 may be 0.1 to 0.2 mm, and the spring plate 2 may span this gap, e.g., having a thickness or other dimension of 0.1 to 0.2 mm. As an example, the spring plate 2 may be made of a sheet material, such as stainless steel, having a thickness of 0.1 to 0.2 mm. It should be appreciated, however, that the gap between the top surface of the heat sink 8 and the cap 3, as well as the thickness of material used to form the spring plate 2 may be other values, e.g., from 0.1 to 2 mm or more, and the thickness of the spring plate 2 material need not closely match the height of the gap. However, having the spring plate 2 be made to have a thickness that closely approximates the height of the gap may allow the spring plate 2 to at least partially and/or completely fill the gap, aiding in thermal conduction across the gap. In some cases, the spring plate 2 may deform elastically as well as plastically when squeezed between the heat sink 8 and the cap 3. Elastic deformation may allow the spring plate 2 to exert a resilient bias on the cap 3 and heat sink 8, and plastic deformation, e.g., by extrusion, may allow the spring plate 2 to completely fill the gap between the heat sink 8 and cap 3 at least in some areas.

In accordance with aspects of the invention, the spring plate 2 may have an upper portion that contact the cap 3 and a lower portion that contacts the heat sink 8. The upper and lower portions of the spring plate 2 may be joined so that the spring plate 2 can exert a resilient bias on the cap 3 and heat sink 8. For example, FIG. 4 shows a side view of the spring plate 2 that includes a pair of upper portions 6 on opposite ends of the spring plate 2 and a lower portion 7 between the upper portions 6. In this embodiment, the spring plate 2 includes bends between the upper and lower portions 6, 7 which defines a U-shape or channel-shape and provides an elastic connection between the upper and lower portions 6, 7, enabling the spring plate 2 to provide a resilient bias on the cap 3 (upwardly) and the heat sink 8 (downwardly). The upper portions 6 may be located in an upper plane that is positioned above a lower plane in which the lower portion 7 is located. As can be seen in FIG. 3, the upper portions 6 of the spring plate 2 may be received into locating grooves or slots in the cavity 4 which may help properly locate the spring plate 2 relative to the cap 3 as well as the heat sink 8. The lower portion 7 of the spring plate 2 may span across and contact a plurality of fins of the heat sink 8, e.g., providing a conductive path for heat transfer. The spring plate 2 may be formed by stamping of a sheet material or other suitable process.

Forming the spring plate 2 of a metal material, such as stainless steel may provide several advantages. For example, where the cap 3 is made of a copper material, the stainless steel spring plate 2 may reduce or avoid electrochemical corrosion after long-term contact with the copper material, improving the stability of the heat exchanger 10. Alternately, or in addition, the spring plate 2 may allow for high temperature joining operations to attach the cap 3 and base 1 together, such as vacuum brazing, welding or other high heat processes. This is in contrast to use of a rubber or other material in the gap between the heat sink 8 and cap 3 which cannot tolerate relatively high temperatures, e.g., of 500 degrees C. or more, over relatively long periods, e.g., of an hour or more. Also, in some embodiments, the spring plate 2 may suitably fill the gap between the top surface of the heat sink 8 and the cap 3 so that the spring plate 2 is attached to the heat sink 8 and the cap 3 during a vacuum brazing or other similar attachment process. That is, the spring plate 2 may provide a suitable filler in the gap between the heat sink 8 and the cap 3 so that a brazing filler material will flow into the gap to join the cap 3, spring plate 2 and heat sink 8 top surface together during a vacuum brazing process. This may further aid in thermal conduction between the cap 3 and the heat sink 8.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

The use of “including,” “comprising,” “having,” “containing,” “involving,” and/or variations thereof herein, is meant to encompass the items listed thereafter and equivalents thereof as well as additional items.

It should also be understood that, unless clearly indicated to the contrary, in any methods claimed herein that include more than one step or act, the order of the steps or acts of the method is not necessarily limited to the order in which the steps or acts of the method are recited.

While aspects of the invention have been described with reference to various illustrative embodiments, such aspects are not limited to the embodiments described. Thus, it is evident that many alternatives, modifications, and variations of the embodiments described will be apparent to those skilled in the art. Accordingly, embodiments as set forth herein are intended to be illustrative, not limiting. Various changes may be made without departing from the spirit of aspects of the invention.

1. A liquid cold plate heat exchanger, comprising:
a base having an upper surface;
a heat sink having a plurality of fins arranged on the upper surface of the base, the plurality of fins defining a top surface of the heat sink;
a cap having a lower surface positioned over the upper surface of the base and the heat sink; and
a spring plate positioned between the top surface of the heat sink and the lower surface of the cap,
wherein with the cap secured to the base, the spring plate is arranged to exert an upward bias on the lower surface of the cap and a downward bias on the top surface of the heat sink.

2. The liquid cold plate heat exchanger of claim 1, wherein the base, heat sink, cap and spring plate are arranged to withstand a temperature of 500 degrees C. for at least 1 hour.

3. The liquid cold plate heat exchanger of claim 1, wherein the base, heat sink, cap and spring plate are arranged to withstand a temperatures required to secure the lower surface of the cap to the upper surface of the base by vacuum brazing.

4. The liquid cold plate heat exchanger of claim 1, wherein the base and heat sink are made of copper or aluminum.

5. The liquid cold plate heat exchanger of claim 1, wherein the spring plate includes a heat sink contacting portion that contacts the heat sink top surface and a cap contacting portion that contacts the lower surface of the cap, and the heat sink contacting portion is located below the cap contacting portion.

6. The liquid cold plate heat exchanger of claim 5, wherein the heat sink contacting portion is between first and second cap contacting portions located at opposite ends of the spring plate.

7. The liquid cold plate heat exchanger of claim 7, wherein the spring plate is formed of a bent metal sheet that forms the heat sink contacting portion and the first and second cap contacting portions, and wherein the heat sink contacting portion is located in a lower plane positioned below an upper plane in which the first and second cap contacting portions are located.

8. The liquid cold plate heat exchanger of claim 1, wherein the spring plate is formed of a metal sheet having a thickness of 0.1 to 0.2 mm.

9. The liquid cold plate heat exchanger of claim 1, wherein the spring plate is formed from a stainless steel metal sheet.

10. The liquid cold plate heat exchanger of claim 1, wherein the spring plate is formed by stamping a metal sheet material, and where in the stamped spring plate is elastic.

11. The liquid cold plate heat exchanger of claim 1, wherein the plurality of fins includes fins having a space of 0.1 to 0.2 mm between adjacent fins.

12. The liquid cold plate heat exchanger of claim 1, wherein the top cap is formed of copper or aluminum.

13. The liquid cold plate heat exchanger of claim 1, wherein a portion of the upper surface of the base and a portion of the lower surface of the cap are secured together by vacuum brazing.

14. The liquid cold plate heat exchanger of claim 1, wherein a portion of the upper surface of the base and a portion of the lower surface of the cap are secured together to form a liquid-tight seal around the heat sink.

15. The liquid cold plate heat exchanger of claim 1, wherein the cap includes a cavity in a portion of the lower surface arranged to receive and contact the spring plate and to receive at least a portion of the heat sink.

16. The liquid cold plate heat exchanger of claim 15, wherein the spring plate includes an upper portion that contacts the cap in the cavity, and includes a lower portion that contacts the top surface of the heat sink.

17. The liquid cold plate heat exchanger of claim 1, wherein a distance between lower surface of the cap in the cavity and the top surface of the heat sink is between 0.1 mm and 0.2 mm.

18. A liquid cold plate heat exchanger, comprising:
a base having an upper surface;
a heat sink having a plurality of fins arranged on the upper surface of the base, the plurality of fins defining a top surface of the heat sink;
a cap having a lower surface and a cavity formed in a portion of the lower surface, the cavity positioned over the upper surface of the base and the heat sink; and
a spring plate positioned between the top surface of the heat sink and the lower surface of the cap at the cavity,
wherein a portion of the lower surface of the cap around the cavity is secured to a portion of the upper surface of the base around the heat sink, and the spring plate is arranged to exert an upward bias on the lower surface of the cap at the cavity and a downward bias on the top surface of the heat sink.

19. The liquid cold plate heat exchanger of claim 18, wherein the portion of the upper surface of the base and the portion of the lower surface of the cap are secured together by vacuum brazing.

20. The liquid cold plate heat exchanger of claim 18, wherein the spring plate is deformed elastically and/or plastically with contact with the cap and heat sink.
